(19) United States
(12) Patent Application Publication
(10) Pub. No.: US 2025/0199079 A1
(43) Pub. Date: Jun. 19, 2025

(54) VOLTAGE DETECTION CIRCUIT, CHARGE AND DISCHARGE CONTROL DEVICE, AND BATTERY DEVICE

(71) Applicant: ABLIC Inc., Nagano (JP)

(72) Inventors: Yasuhiro KAMIJIMA, Nagano (JP); Kazuki OKOCHI, Nagano (JP); Hiroshi SAITO, Nagano (JP); Keiichi MURAKAWA, Nagano (JP)

(73) Assignee: ABLIC Inc., Nagano (JP)

(21) Appl. No.: 18/822,508

(22) Filed: Sep. 3, 2024

(30) Foreign Application Priority Data
Dec. 19, 2023 (JP) 2023-213751

(51) Int. Cl. G01R 31/3835; G01R 31/396; H01M 10/44; H01M 10/48; H01M 50/51; H02J 7/00

(52) U.S. Cl. CPC G01R 31/3835; G01R 31/396; H01M 10/441; H01M 10/482; H01M 50/51; H02J 7/0014; H02J 7/00302; H02J 7/0047

(57) ABSTRACT

A voltage detection circuit 101 includes: a bleeder resistance circuit BR, dividing the battery voltage into divided voltages VD1 and VD2; a comparator C2, receiving the divided voltage VD1 and a reference voltage VREF and outputting a signal indicating a normal state or an overcharge state; a switch M3, connected in parallel with a resistor part R2 and turned on in the overcharge state; a comparator C1, receiving the divided voltage VD2 and the reference voltage VREF and outputting a signal indicating the normal state or a low-voltage state; a switch M1, connected between a high-voltage side of a resistor part R3 and an input part of the comparator C1 and turned on in the low-voltage state; and a switch M2, connected between a low-voltage side of the resistor part R3 and the input part of the comparator C1 and turned off in the low-voltage state.

### CROSS-REFERENCE TO RELATED APPLICATION

This application claims the priority benefits of Japanese application no. 2023-213751, filed on Dec. 19, 2023. The entirety of the above-mentioned patent application is hereby incorporated by reference herein and made a part of this specification.

### BACKGROUND

### Technical Field

The present invention relates to a voltage detection circuit, a charge and discharge control device, and a battery device.

### Description of Related Art

Secondary batteries such as lithium-ion batteries are widely used in various fields as power sources for portable devices, power tools, transportation equipment, and the like. For devices requiring higher voltages, battery packs with multiple battery cells connected in series are utilized. To ensure safe use of these battery packs, a protection circuit is connected to the battery pack to monitor overcharge and over-discharge (low-voltage) of each battery cell, thereby preventing imbalances due to individual differences among the battery cells.

This protection circuit often includes a comparator that compares a divided battery voltage with a reference voltage to detect conditions such as overcharging. In such cases, to prevent unstable operation when the battery voltage fluctuates, a “hysteresis” is provided, where the detection voltage differs from the release voltage.

For example, an overcharge and over-discharge prevention circuit has been proposed that can balance individual battery cells during overcharge and over-discharge by providing hysteresis in overcharge detection and over-discharge detection (see Patent Document 1 (Japanese Patent Application Laid-Open (JP-A) No. H05-49181)).

One aspect of the present invention provides a voltage detection circuit that achieves miniaturization, provides hysteresis in overcharge detection and over-discharge detection, and does not decrease in overcharge detection accuracy even in the case of cell balance disruption.

### SUMMARY

A voltage detection circuit according to one embodiment of the present invention detects a battery voltage in each of multiple battery cells to collectively control charging and discharging of the battery cells. The voltage detection circuit includes:
a bleeder resistance circuit, in which multiple resistor parts are connected in series and dividing the battery voltage into a first divided voltage and a second divided voltage;
an overcharge detection comparator, receiving the first divided voltage of the bleeder resistance circuit and a reference voltage and outputting an output signal indicating a normal state or an overcharge state;
an overcharge switch, connected in parallel with a first resistor part in the bleeder resistance circuit, turned off in the normal state and turned on in the overcharge state;
a low-voltage detection comparator, receiving the second divided voltage of the bleeder resistance circuit and the reference voltage and outputting an output signal indicating the normal state or a low-voltage state;
a first low-voltage switch, connected between a high-voltage side of a second resistor part in the bleeder resistance circuit and an input part of the low-voltage detection comparator by which the first divided voltage is received, turned off in the normal state and turned on in the low-voltage state; and
a second low-voltage switch, connected between a low-voltage side of the second resistor part in the bleeder resistance circuit and the input part of the low-voltage detection comparator, turned on in the normal state and turned off in the low-voltage state.

The voltage detection circuit is connected in parallel to each of the battery cells, respectively, and a plurality of the bleeder resistance circuits are connected in series.

### BRIEF DESCRIPTION OF THE DRAWINGS

FIG. 1 is a circuit diagram illustrating the battery device and the charge and discharge control circuit in one embodiment of the present invention.

FIG. 2 is a circuit diagram illustrating the voltage detection circuit in one embodiment of the present invention.

FIG. 3 is a circuit diagram illustrating a conventional voltage detection circuit.

### DESCRIPTION OF THE EMBODIMENTS

According to one aspect of the present invention, a voltage detection circuit may be provided that achieves miniaturization, provides hysteresis in overcharge detection and over-discharge detection, and does not decrease in overcharge detection accuracy even in the case of cell balance disruption.

The present invention is based on the insight that in the circuit configuration described in Patent Document 1, when attempting to provide hysteresis for overcharge and over-discharge detection, two switches are required for each, resulting in an increased number of transistors serving as switches and more complex wiring, making miniaturization difficult.

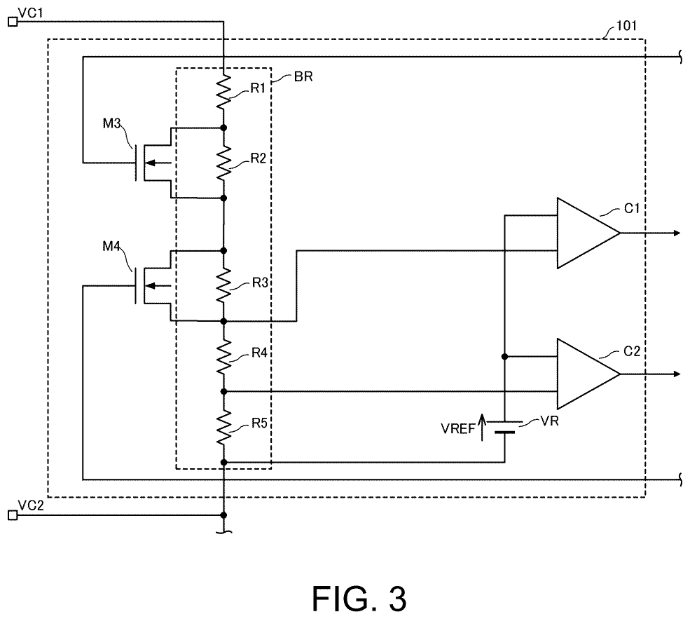

For miniaturization, in the case where a simplified circuit configuration is adopted as shown in FIG. 3, with one switch each for overcharge and over-discharge detection, there were cases where the overcharge detection voltage would change due to cell balance disruption, leading to a decrease in overcharge detection accuracy, as will be detailed later. Specifically, in protection circuits known as “second protect,” it is crucial to interrupt the circuit in case of overcharge, and even if detection accuracy is improved in other parts, it is not perfect if overcharge detection accuracy decreases due to cell balance disruption.

Thus, in one embodiment of the present invention, a circuit configuration is provided that achieves miniaturization, provides hysteresis in overcharge detection and over-discharge detection, and does not decrease in overcharge detection accuracy even in the case of cell balance disruption.

Hereinafter, the embodiments of the present invention are described with reference to the

### DRAWINGS

In addition, in the drawings, the same component parts may be given the same signs, and redundant descriptions may be omitted.

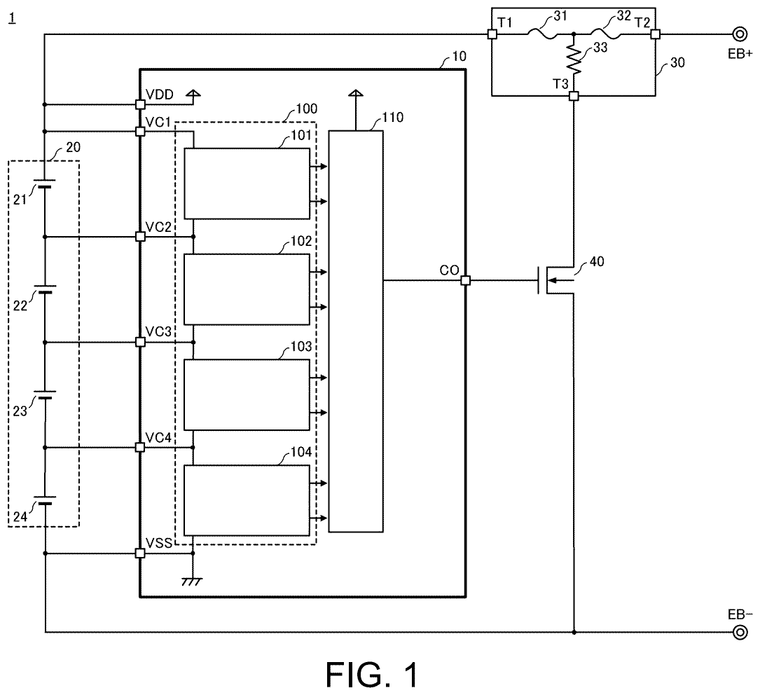

FIG. 1 is a circuit diagram illustrating the battery device and a charge and discharge control circuit in one embodiment of the present invention.

The battery device 1 is a power supply device that allows safe use of lithium-ion battery cells connected in series, and has a protection IC (integrated circuit) called “second protect” that may stop charging. This battery device 1 includes a charge and discharge control device 10 as the protection IC thereof, a battery pack 20 with four battery cells 21 to 24 connected in series, an SCP (self control protector) 30, a charge control FET (field effect transistor) 40, an external terminal EB+, and an external terminal EB−.

During charging of the battery device 1, a charging device is connected between the external terminal EB+ and the external terminal EB−. Also, when using the battery device 1, a load device is connected between the external terminal EB+ and the external terminal EB−.

The charge and discharge control device 10 detects the battery voltages of the battery cells 21 to 24 in the battery pack 20, respectively, and controls charging and discharging according to the detected battery voltages.

The charge and discharge control device 10 controls to stop charging to the battery pack 20 in the case where any of the battery cells 21 to 24 is in the overcharge state. In addition, the charge and discharge control device 10 controls to stop discharging from the battery pack 20 by shutting down other functions in the case of any of the battery cells 21 to 24 reaching a low-voltage state (over-discharge state).

Here, “overcharge state” refers to a condition where the battery voltage of any of the battery cells 21 to 24 exceeds a predetermined overcharge detection voltage and the time during which the battery voltage exceeds the overcharge detection voltage surpasses a predetermined period of time. In addition, in the case where the battery voltage drops below the overcharge release voltage within the predetermined period of time, a “normal state” is returned. Furthermore, to prevent unstable operation when the battery voltage fluctuates near the overcharge detection voltage, the overcharge release voltage is set lower than the overcharge detection voltage, establishing an “overcharge hysteresis voltage” (=overcharge detection voltage-overcharge release voltage) to stabilize the operation. Specifically, for example, the overcharge detection voltage is set to 4.6V, and the overcharge release voltage is set to 4.3V.

The “low-voltage state” refers to a condition where the battery voltage of any of the battery cells 21 to 24 drops below a predetermined low-voltage detection voltage and the time during which the battery voltage remains below the low-voltage detection voltage continues for a predetermined period of time or longer. In addition, in the case where the battery voltage rises above a recovery voltage within the predetermined period of time, the “normal state” is returned. Furthermore, to prevent unstable operation when the battery voltage fluctuates near the low-voltage detection voltage, the recovery voltage is set higher than the low-voltage detection voltage, establishing a “low-voltage hysteresis voltage” (=recovery voltage-low-voltage detection voltage) to stabilize the operation. Specifically, for example, the low-voltage detection voltage is set to 2.5V, and the recovery voltage is set to 2.7V.

The “normal state” refers to a condition where the battery voltages of all battery cells 21 to 24 are at or below the overcharge detection voltage and at or above the low-voltage detection voltage.

Further, other functions may be appropriately selected according to the purpose without particular limitation. For example, in the case where the load device is a laptop computer and the charge and discharge control device 10 is provided with a constant voltage circuit that supplies a constant voltage to the real-time clock circuit in the external circuitry of the load device, the constant voltage circuit corresponds to the other functions.

The charge and discharge control device 10 includes a voltage detection part 100, a control unit 110, a power supply terminal VDD, a ground terminal VSS, input parts VC1 to VC4, and an output port CO. The battery cells 21 to 24 of the battery pack 20 are connected to the power supply terminal VDD, the input parts VC1 to VC4, and the ground terminal VSS of the charge and discharge control device 10 and are connected in such a way that the battery voltages of the battery cells 21 to 24 are detected individually.

The battery pack 20 has a positive side connected to the external terminal EB+ and a negative side connected to the external terminal EB−. The SCP 30, which is a fuse circuit for interrupting the charging path during charging, is connected between the external terminal EB+ and the positive side of the battery pack 20. A terminal T1 of the SCP 30 is connected to the battery pack 20, and a terminal T2 of the SCP 30 is connected to the external terminal EB+.

The SCP 30 has fuses 31 and 32 connected in series between the terminal T1 and the terminal T2, and a resistor element 33 is connected between a connection part of the fuses 31 and 32 and a terminal T3.

The fuses 31 and 32 melt and interrupt the circuit in an over-current state. Further, the charge control FET 40 is turned on in the overcharge state, the resistor element 33 acting as a heater is energized, and the fuses 31 and 32 are melted by the heat generated by the resistor element 33, thereby interrupting the circuit.

It should be noted that while the resistor element 33 is singular in this embodiment, it may also be plural.

The gate terminal of the charge control FET 40 is connected to the output port CO of the charge and discharge control device 10. The charge control FET 40 is turned on and off based on the control signal from the charge and discharge control device 10, being turned off in the normal state and turned on in the overcharge state.

Thus, the operation of the charge and discharge control device 10 is such that the charge control FET 40 is kept turned off in the normal state, and the charge control FET 40 is turned on in the overcharge state when charging to energize the resistor element 33, causing the fuses 31 and 32 to melt from the heat generated, thereby stopping the charging. Further, in the low-voltage state, the charge and discharge control device 10 stops other functions thereof and stops discharging from the battery pack 20.

Next, the voltage detection part 100 and the control unit 110 of this charge and discharge control device 10 are described in detail.

The voltage detection part 100 includes voltage detection circuits 101 to 104 connected to the positive side and negative side of each battery cell for detecting the battery voltage of each of the battery cells 21 to 24.

Since the voltage detection circuits 101 to 104 are all formed similarly, the following description focuses on the voltage detection circuit 101, and the descriptions for the voltage detection circuits 102 to 104 are omitted.

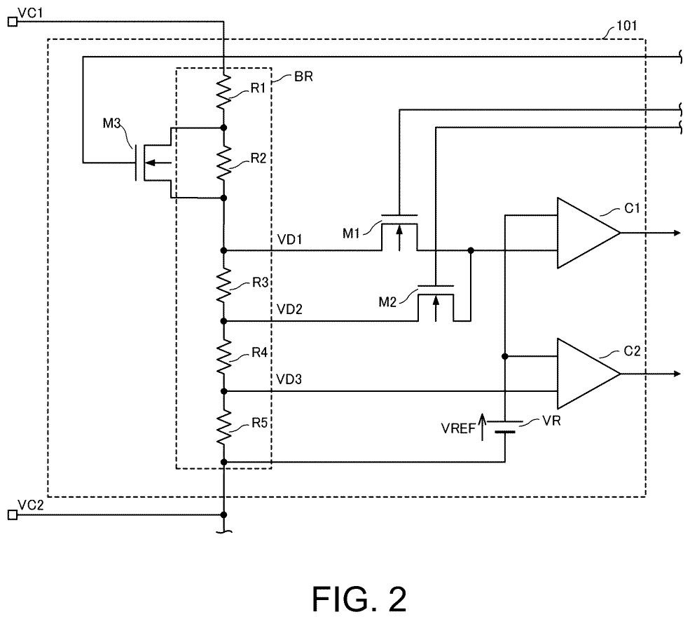

FIG. 2 is a circuit diagram illustrating the voltage detection circuit in one embodiment of the present invention.

As shown in FIG. 2, the voltage detection circuit 101 includes a bleeder resistance circuit BR, a reference voltage source VR, a low-voltage detection comparator C1, low-voltage switches M1 and M2, an overcharge detection comparator C2, and an overcharge switch M3.

The bleeder resistance circuit BR is a voltage divider circuit, in which multiple resistor parts R1, R2, R3, R4, and R5 are sequentially connected in series from the positive terminal to the negative terminal of the battery cell 21.

It should be noted that each resistor part may be formed from a single resistor element or multiple resistor elements. Further, each resistor part may include a fuse element to allow for resistance value adjustment, and in many cases, the detection accuracy is improved by trimming using this fuse element.

This bleeder resistance circuit BR divides the battery voltage of the battery cell 21 into a divided voltage VD1 (first divided voltage), a divided voltage VD2 (second divided voltage), and a divided voltage VD3.

The divided voltage VD1 is output from the connection part of the resistor parts R2 and R3 and is received by the first input part of the low-voltage detection comparator C1 via the low-voltage switch M1.

The divided voltage VD2 is output from the connection part of the resistor parts R3 and R4 and is received by the first input part of the low-voltage detection comparator C1 via the low-voltage switch M2.

The divided voltage VD3 is output from the connection part of the resistor parts R4 and R5 and is received by the first input part of the overcharge detection comparator C2.

The reference voltage source VR outputs the generated reference voltage VREF to the second input part of the low-voltage detection comparator C1 and the second input part of the overcharge detection comparator C2, respectively.

The low-voltage detection comparator C1 receives either the divided voltage VD1 or the divided voltage VD2 at the first input part and receives the reference voltage VREF at the second input part. Then, the low-voltage detection comparator C1 compares either of the divided voltages with the reference voltage VREF and detects a low-voltage of the battery cell 21 by outputting an H-level or L-level output signal to the control unit 110 according to the comparison result.

The low-voltage switches M1 and M2 is capable of generating a “low-voltage hysteresis voltage” and preventing the overcharge detection accuracy from decreasing even in the case where any of the battery cells is in a low-voltage state.

First, the following describes how the low-voltage switches M1 and M2 generate a “low-voltage hysteresis voltage”

The low-voltage switch M1 is a transistor and is connected between the high-voltage side of the resistor part R3, which is the second resistor part in the bleeder resistance circuit BR, and the first input part of the low-voltage detection comparator C1. The gate terminal of the low-voltage switch M1 is connected to the control unit 110, and the low-voltage switch M1 is turned off in the normal state and turned on in the low-voltage state in response to a control signal from the control unit 110.

The low-voltage switch M2 is a transistor and is connected between the low-voltage side of the resistor part R3 in the bleeder resistance circuit BR and the first input part of the low-voltage detection comparator C1. The gate terminal of the low-voltage switch M2 is connected to the control unit 110, and the low-voltage switch M2 is turned on in the normal state and turned off in the low-voltage state in response to a control signal from the control unit 110.

Thus, by switching the low-voltage switches M1 and M2, the first input part of the low-voltage detection comparator C1 receives the divided voltage VD1 in the low-voltage state and receives the divided voltage VD2 in the normal state, thereby generating a “low-voltage hysteresis voltage”.

The overcharge detection comparator C2 compares the divided voltage VD3 received by the first input part with the reference voltage VREF received by the second input part and detects overcharge of the battery cell 21 by outputting an H-level or L-level output signal to the control unit 110 according to the comparison result.

The overcharge switch M3 is a transistor and is connected in parallel with the resistor part R2, which serves as the first resistor part. The gate terminal of the overcharge switch M3 is connected to the control unit 110, and the overcharge switch M3 is turned off in the normal state and turned on in the overcharge state in response to a control signal from the control unit 110. Thus, by switching the overcharge switch M3, a voltage drop occurs across the resistor part R2 in the normal state, while no voltage drop occurs in the overcharge state, thereby generating an “overcharge hysteresis voltage”. In this way, an “overcharge hysteresis voltage” may be generated with a single switch, thereby achieving miniaturization without the need for complex wiring.

Further, in the overall voltage detection part 100, as shown in FIG. 1, the bleeder resistance circuit BR is provided for each of the battery cells 21 to 24, and the four bleeder resistance circuits are connected in series.

The control unit 110 outputs a control signal that collectively turns on and off the charge control FET 40, the low-voltage switches M1 and M2, and the overcharge switch M3 in all voltage detection circuits 101 to 104, based on the output signal from any of the voltage detection circuits 101 to 104.

Specifically, in the case where all of the battery cells 21 to 24 are in the normal state, the control unit 110 turns off the low-voltage switch M1, turns on the low-voltage switch M2, and turns off the overcharge switch M3 for all of the voltage detection circuits 101 to 104. Further, in the case where any of the battery cells 21 to 24 is in the low-voltage state, the control unit 110 turns on the low-voltage switch M1, turns off the low-voltage switch M2, and turns off the overcharge switch M3 for all of the voltage detection circuits 101 to 104.

Furthermore, in the case where any of the battery cells 21 to 24 is in the overcharge state, the control unit 110 turns on the low-voltage switch M1, turns off the low-voltage switch M2, and turns on the overcharge switch M3 for all of the voltage detection circuits 101 to 104. Then, the case of a “cell balance disruption” is considered, for example, in the case where

the battery cells 21 to 23 are in the normal state, and only the battery cell 24 transitions from the normal state to the low-voltage state. In this case, to control the low-voltage state, the control unit 110 turns on the low-voltage switch M1, turns off the low-voltage switch M2, and keeps the overcharge switch M3 turned off for all the voltage detection circuits 101 to 104.

Even in the case of such a cell balance disruption, the voltage detection circuits 101 to 104 maintain the same value for the overcharge detection voltage VCU (not shown in the drawings as this is a standard value) in the normal state and the low-voltage state.

Specifically, in the case where the resistance values of the resistor parts R1, R2, R3, R4, and R5 are denoted as r1, r2, r3, r4, and r5, respectively, the following applies.

In the normal state, where the low-voltage switch M1 is turned off, the low-voltage switch M2 is turned on, and the overcharge switch M3 is turned off, the overcharge detection voltage VCU is given by the following equation (1).

$$V CU = ( ( r 1 + r 2 + r 3 + r 4 + r 5 ) / r 5 ) \times V REF \qquad ( 1 )$$

In the low-voltage state, where the low-voltage switch M1 is turned on, the low-voltage switch M2 is turned off, and the overcharge switch M3 is turned off, the overcharge detection voltage VCU is given by the following equation (2).

$$V CU = ( ( r 1 + r 2 + r 3 + r 4 + r 5 ) / r 5 ) \times V REF \qquad ( 2 )$$

Thus, as shown in the above equations (1) and (2), even in the case of a cell balance disruption, the overcharge detection voltage VCU in one embodiment of the present invention does not change between the normal state and the low-voltage state, so the overcharge detection accuracy does not decrease. In other words, although it may be rare for one battery cell to be in the low-voltage state while another battery cell to be in the overcharge state, the battery device 1 is capable of accurately interrupting the circuit in the overcharge state using the charge and discharge control device 10 including the voltage detection circuits 101 to 104.

Hereinafter, a conventional voltage detection circuit is described for comparison with one embodiment of the present invention.

FIG. 3 is a circuit diagram illustrating a conventional voltage detection circuit. As shown in FIG. 3, the conventional voltage detection circuit is similar to the voltage detection circuit 101 of one embodiment of the present invention, except that a low-voltage switch M4 is connected in parallel with the resistor part R3 instead of the low-voltage switches M1 and M2 in the voltage detection circuit 101.

This low-voltage switch M4 is a transistor that is turned off in the normal state and turned on in the low-voltage state, thereby generating a “low-voltage hysteresis voltage”.

In such a conventional voltage detection circuit, the overcharge detection voltage VCU changes between the normal state and the low-voltage state due to cell balance disruption. Specifically, the situation is as follows.

In the normal state, in the case where the overcharge switch M3 is turned off and the low-voltage switch M4 is turned on, the overcharge detection voltage VCU is given by the following equation (3):

$$V CU = ( ( r 1 + r 2 + r 4 + r 5 ) / r 5 ) \times V REF \qquad ( 3 )$$

In the low-voltage state, in the case where the overcharge switch M3 is turned off and the low-voltage switch M4 is turned off, the overcharge detection voltage VCU is given by the following equation (4):

$$V CU = ( ( r 1 + r 2 + r 3 + r 4 + r 5 ) / r 5 ) \times V REF \qquad ( 4 )$$

Thus, as shown in the above equations (3) and (4), in the case of cell balance disruption, the overcharge detection voltage VCU in the conventional voltage detection circuit changes between the normal state and the low-voltage state, resulting in decreased overcharge detection accuracy. Specifically, in charge and discharge control devices known as “second protect” devices, it is crucial to interrupt the circuit in an overcharge state, and even if detection accuracy is improved by trimming with fuse elements as mentioned above, it is not perfect if overcharge detection accuracy decreases due to cell balance disruption.

Thus, in one embodiment of the present invention, as shown in FIG. 2, low-voltage switches M1 and M2 are provided instead of the low-voltage switch M4, thereby preventing the overcharge detection voltage from changing between the normal state and the low-voltage state and ensuring that the overcharge detection accuracy does not decrease even in the case of cell balance disruption.

As described above, the voltage detection circuit in one embodiment of the present invention is a circuit that detects a battery voltage in each of multiple battery cells to collectively control charging and discharging for the battery cells. This voltage detection circuit has a bleeder resistance circuit in which multiple resistor parts are connected in series and dividing the battery voltage into a first divided voltage and a second divided voltage. In addition, this voltage detection circuit further includes an overcharge detection comparator that receives the first divided voltage and a reference voltage and outputs a signal indicating a normal state or an overcharge state, and an overcharge switch connected in parallel with the first resistor part, which is turned off in the normal state and turned on in the overcharge state. Furthermore, this voltage detection circuit further includes a low-voltage detection comparator that receives the second divided voltage and a reference voltage and outputs a signal indicating a normal state or a low-voltage state. Moreover, this voltage detection circuit further includes a first low-voltage switch connected between the high-voltage side of the second resistor part and the input part of the low-voltage detection comparator, which is turned off in the normal state and turned on in the low-voltage state, and a second low-voltage switch connected between the low-voltage side of the second resistor part and the input part of the low-voltage detection comparator, which is turned on in the normal state and turned off in the low-voltage state. Then, this voltage detection circuit is connected in parallel to each of the multiple battery cells, with multiple bleeder resistance circuits connected in series.

As a result, this voltage detection circuit achieves miniaturization, provides hysteresis in overcharge detection and over-discharge detection, and does not decrease in overcharge detection accuracy even in the case of cell balance disruption.

Although this embodiment has been described using the example of a second protect for a lithium-ion battery, it is not limited thereto, and the circuit may be applied to any device that uses a circuit that detect voltage.

It should be noted that the control unit may be provided with various circuits such as delay circuits and oscillator circuits to control charging and discharging of the battery pack based on the output signals from each comparator.

Further, although the above embodiment describes the bleeder resistance circuit as having five resistor parts, it is not limited thereto, and the circuit requires at least the first resistor part and the second resistor part.

Furthermore, although the above embodiment describes four battery cells, it is not limited thereto, and any plurality of battery cells may be used.

Furthermore, although various switches are depicted in the drawings as NMOS (N-type metal oxide semiconductor) transistors, it is not limited thereto, and any element with switching functionality may be used. For example, the various switches may be PMOS (P-type metal oxide semiconductor) transistors or junction FETs, taking into consideration the conductivity type of the semiconductor substrate and substrate bias effects.

What is claimed is:

1. A voltage detection circuit, detecting a battery voltage in each of a plurality of battery cells to collectively control charging and discharging of the battery cells, the voltage detection circuit comprising:
a bleeder resistance circuit, in which a plurality of resistor parts are connected in series and dividing the battery voltage into a first divided voltage and a second divided voltage;
an overcharge detection comparator, receiving the first divided voltage of the bleeder resistance circuit and a reference voltage and outputting an output signal indicating a normal state or an overcharge state;
an overcharge switch, connected in parallel with a first resistor part in the bleeder resistance circuit, turned off in the normal state and turned on in the overcharge state;
a low-voltage detection comparator, receiving the second divided voltage of the bleeder resistance circuit and the reference voltage and outputting an output signal indicating the normal state or a low-voltage state;
a first low-voltage switch, connected between a high-voltage side of a second resistor part in the bleeder resistance circuit and an input part of the low-voltage detection comparator by which the first divided voltage is received, turned off in the normal state and turned on in the low-voltage state; and
a second low-voltage switch, connected between a low-voltage side of the second resistor part in the bleeder resistance circuit and the input part of the low-voltage detection comparator, turned on in the normal state and turned off in the low-voltage state,
wherein the voltage detection circuit is connected in parallel to each of the battery cells, respectively, and a plurality of the bleeder resistance circuits are connected in series.

2. A charge and discharge control circuit, comprising:
a voltage detection circuit according to claim 1, connected in parallel to each of the plurality of battery cells, respectively; and
a control unit, collectively controlling a plurality of the voltage detection circuits,
wherein the control unit controls the overcharge switch, the first low-voltage switch, and the second low-voltage switch, respectively, based on an output signal of the overcharge detection comparator and an output signal of the low-voltage detection comparator.

3. A battery device, comprising:
a charge and discharge control circuit according to claim 2;
a battery pack, equipped with the plurality of battery cells connected in series; and
a charge control FET, connected in parallel with the battery pack between a pair of external terminals.
